(19) United States
(12) Patent Application Publication
(10) Pub. No.: US 2002/0001859 A1
(43) Pub. Date: Jan. 3, 2002

(54) Method for forming a ferroelectric memory device

(76) Inventors: Bee-Lyong Yang, Ichon-shi (KR); Nam-Soo Kang, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/883,189

(22) Filed: Jun. 19, 2001

(30) Foreign Application Priority Data
Jun. 30, 2000 (KR) 2000-37362

(51) Int. Cl. H01L 21/00; B05D 5/12

(52) U.S. Cl. 438/3; 427/128; 427/131

(57) ABSTRACT

A method for manufacturing a ferroelectric memory device including steps of forming a ferroelectric layer, carrying out a rapid thermal process (RTP) to the ferroelectric layer to form perovskite crystal nuclei therein, and carrying out a heat treatment to the ferroelectric layer below 650° C. in the presence of O₂ gas to crystallize the ferroelectric layer.

### FIELD OF THE INVENTION

The present invention relates to a method for manufacturing a ferroelectric memory device and, more particularly, to a method for manufacturing a ferroelectric memory device which is capable of preventing a metal layer from being oxidized during crystallization of a ferroelectric material.

### DESCRIPTION OF THE PRIOR ART

In a semiconductor memory device, by using a ferroelectric material in a capacitor, several studies have been undertaken to overcome a limit of refresh in a conventional DRAM and to achieve a large capacitance. A ferroelectric random access memory (FeRAM) is one of the nonvolatile memory devices that can store information in a powered-off state and has an operating speed comparable to that of the conventional DRAM.

The ferroelectric material has a dielectric constant being on the order of 10²-10³ in normal temperature and has two stabilized remanent polarization states. Therefore, the ferroelectric material is suitable for application to a nonvolatile memory device as a capacitor dielectric. The nonvolatile memory device utilizing the ferroelectric material inputs a signal by changing an orientation of polarization to that of an electric field applied thereto and, when the electric field is removed, stores a digital signal “1” or “0” by an orientation of remanent polarization.

SBT (SrBi₂Ta₂O₉) is used as a capacitor dielectric in FeRAM and formed with a perovskite crystallization structure to secure desirable ferroelectric capacitor characteristics. In a conventional method, the perovskite structure can be obtained by carrying out a heat treatment in the presence of O₂ gas for at least 30 minutes at 700° C. However, if the heat treatment is carried out in the presence of O₂ gas for a long time, a barrier metal, located at the bottom of the capacitor, chemically reacts with the O₂ gas, thereby lifting the barrier metal and rapidly increasing a contact resistance. To overcome these problems, there is a demand for the development of a stable barrier metal which does not react with an O₂ gas at a temperature higher than 700 ° C.

### SUMMARY OF THE INVENTION

It is, therefore, an object of the present invention to provide a method for manufacturing a ferroelectric memory device which prevents a metal layer from chemically reacting with a ferroelectric layer during the heat treatment of the ferroelectric layer.

In accordance with one aspect of the present invention, there is provided a method for manufacturing a ferroelectric memory device, the method comprising steps of forming a ferroelectric layer, carrying out a rapid thermal process (RTP) to the ferroelectric layer to form a perovskite crystal nuclear therein, and carrying out a heat treatment to the ferroelectric layer below 650° C. in the presence of O₂ gas to crystallize the ferroelectric layer.

In accordance with another aspect of the present invention, there is provided a method for manufacturing a ferroelectric memory device, the method comprising steps of preparing a semiconductor substrate provided with transistors, forming an interlayer dielectric (ILD) layer on the transistors, forming a barrier metal layer on the ILD layer, forming a bottom electrode layer on the barrier metal layer, forming a ferroelectric layer on the bottom electrode layer, carrying out RTP to the ferroelectric layer to form a perovskite crystal nuclear therein, and carrying out a heat treatment to the ferroelectric layer below 650° C. in the presence of O₂ gas to crystallize the ferroelectric layer.

### BRIEF DESCRIPTION OF THE DRAWINGS

The above and other objects and features of the present invention will become apparent from the following description of the preferred embodiments given in conjunction with the accompanying drawings, in which;

FIGS. 1 to 5 are sectional views illustrating a method for manufacturing a ferroelectric memory device in accordance with the present invention.

### DETAILED DESCRIPTION OF THE PREFERRED EMBODIMENTS

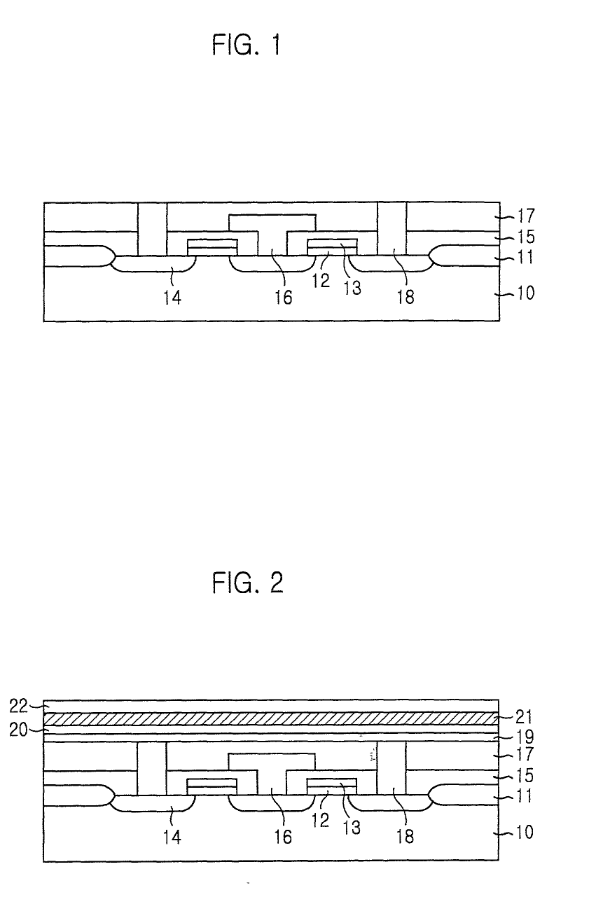

There are provided in FIGS. 1 to 5 cross sectional views setting forth a method for manufacturing a ferroelectric memory device in accordance with preferred embodiments of the present invention.

In FIG. 1, there is shown a semiconductor substrate 10 provided with transistors each of which includes an isolation region 11, a gate dielectric 12, a gate electrode 13, and a source/drain region 14. A first interlayer dielectric (ILD) layer 15 is formed on the transistor. A bit line 16 is formed in a first contact hole in the first ILD layer 15 to electrically connect the source/drain region 14 thereto. A second ILD layer 17 is then formed on the first ILD layer 15 and the bit line 16, and the second ILD 17 layer is selectively etched in such a way that the source/drain region 14 is exposed, thereby obtaining second contact holes. Finally, polysilicon plugs 18 are formed into the second contact holes to electrically connect the transistor to a bottom electrode of capacitor to be formed.

As shown in FIG. 2, an adhesion layer 19 is formed on the polysilicon plugs 18 and the second ILD 17 layer at a thickness ranging from 5 nm to 50 nm. Thereafter, a barrier metal layer 20, which may be made of TiAIN, is formed on the adhesion layer 19 at a thickness ranging from 40 nm to 90 nm. A bottom electrode layer 21 and a ferroelectric layer 22 are formed on the barrier metal layer 20, successively. In the preferred embodiment, the bottom electrode layer 21 has a thickness ranging from 100 nm to 400 nm. The bottom electrode layer 21 is made of a material selected from the group consisting of Pt, Ir, and IrOₓ. It is preferable that the ferroelectric layer 22 be made of BLT (Bi₄₋ₓLaₓTi₃O₁₂), wherein x represents a molar fraction.

After the formation of the ferroelectric layer 22, a rapid thermal process (RTP) is carried out at a temperature higher than 650° C. in the presence of O₂ gas for a period of more than 20 seconds to form perovskite crystallization nuclei in the ferroelectric layer 22. Then, to promote the growth of nuclei at a low temperature, a thermal process is carried out at a temperature lower than 650° C. in the presence of O₂ gas for a period of more than 30 minutes to crystallize the ferroelectric layer 22.

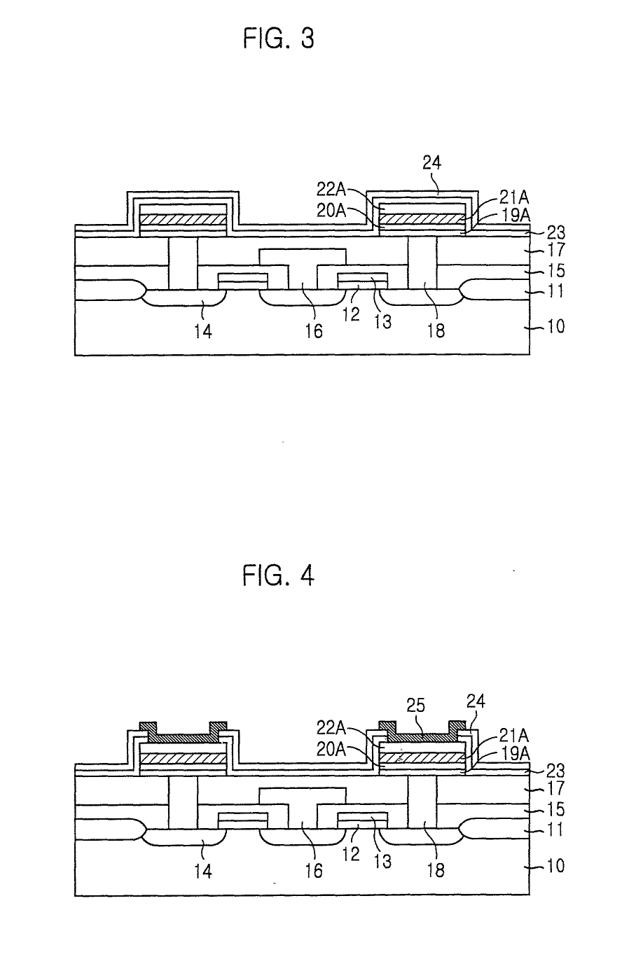

As described in FIG. 3, thereafter the ferroelectric layer 22, the bottom electrode layer 21, the barrier metal layer 20 and the adhesion layer 19 are patterned into a capacitor dielectric 22A, a bottom electrode 21A, a barrier metal 20A and an adhesion film 19A. A tetraethyl orthosilicate (TEOS) layer 23 and an insulating layer 24 are then formed on the capacitor dielectric 22A and the second ILD layer 17 by using chemical vapor deposition (CVD) or physical vapor deposition (PVD). The insulating layer 24 is stacked with AlₓO_{y} and BPSG (Borophosphosilicate Glass). During this process, a hydrogen or H₂O may be generated, and this gas may penetrate into the capacitor dielectric 22A, which results in deteriation of the characteristic of the ferroelectric memory device; therefore, the CVD or PVD, which does not create hydrogen or H₂o, is preferably used.

As shown in FIG. 4, the insulating layer 24 and the TEOS layer 23 are selectively etched to expose the capacitor dielectric 22A over the polysilicon plugs 18. Thereafter, a TiN layer, a Ti layer, a TiN layer and a Pt layer are formed successively and patterned into a predetermined configuration to form a top electrode 25.

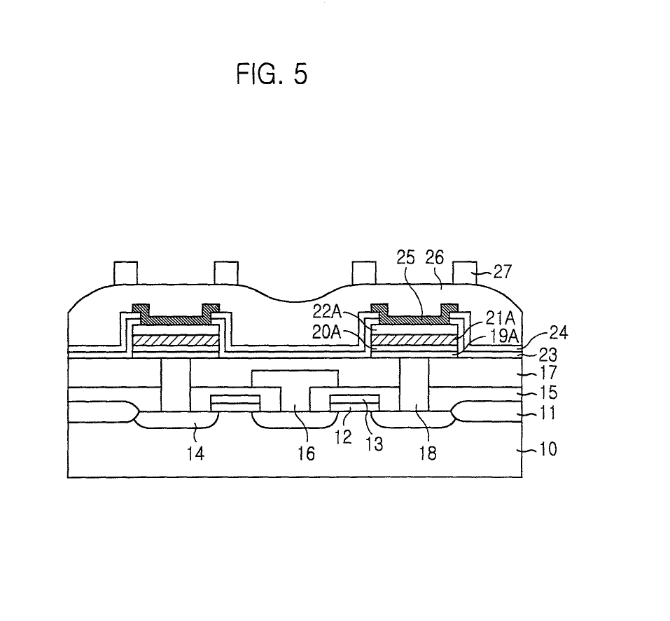

Next, as shown in FIG. 5, a third ILD layer 26 is formed on the top electrode 25 and the insulating layer 24. A metal wiring 27 is formed by using a metal deposition process and a patterning process.

The present invention carries out a ferroelectric crystallization process for forming a perovskite structure below 650° C. to prevent a barrier metal from being oxidized, and so prevent the FeRAM element's electric characteristic deterioration problem, while also increasing yield. Further, the present invention facilitates development of a device having stacked structure which enables application of the already developed post-barrier metal layer process to the FeRAM element manufacturing process, thereby providing economical advantage.

The present invention has a feature of carrying out RTP at a temperature higher than 650° C. in the presence of O₂ gas to form a perovskite crystallization nuclei in the ferroelectric layer. Then, a thermal process is carried out at a temperature lower than 650° C. in the presence of O₂ gas to crystallize the ferroelectric layer.

While the present invention has been described with respect to the particular embodiments, it will be apparent to those skilled in the art that various changes and modifications may be made without departing from the scope of the invention as defined in the following claims.

What is claimed is:

1. A method for manufacturing a ferroelectric memory device, the method comprising steps of:
a) forming a ferroelectric layer;
b) carrying out a rapid thermal process (RTP) to the ferroelectric layer to form perovskite crystal nuclei therein; and
c) carrying out a heat treatment to the ferroelectric layer below 650° C. in the presence of O₂ gas to crystallize the ferroelectric layer.

2. The method of claim 1, wherein the step b) is carried out at a temperature higher than 650° C. in the presence of O₂ gas.

3. A method for manufacturing a ferroelectric memory device, the method comprising steps of:
a) preparing a semiconductor substrate provided with transistors;
b) forming an interlayer dielectric (ILD) layer on the transistors;
c) forming a barrier metal layer on the ILD layer;
d) forming a bottom electrode layer on the barrier metal layer;
e) forming a ferroelectric layer on the bottom electrode layer;
f) carrying out RTP to the ferroelectric layer to form perovskite crystal nuclei therein; and
g) carrying out a heat treatment to the ferroelectric layer lower than 650° C. in the presence of O₂ gas to crystallize the ferroelectric layer.

4. The method of claim 3, wherein the step f) is carried out at a temperature higher than 650° C. in the presence of O₂ gas.

5. The method of claim 4, wherein the ferroelectric layer is made of BLT (Bi₄₋ₓLaₓTi₃O₁₂), with x representing a molar fraction.
